(19) United States
(12) Patent Application Publication
(10) Pub. No.: US 2024/0120226 A1
(43) Pub. Date: Apr. 11, 2024

(54) WAFER PROCESSING APPARATUS

(71) Applicant: ASM IP Holding, B.V., Almere (NL)

(72) Inventor: Yoshiyuki Umeoka, Tokyo (JP)

(21) Appl. No.: 18/474,953

(22) Filed: Sep. 26, 2023

Related U.S. Application Data
(60) Provisional application No. 63/410,687, filed on Sep. 28, 2022.

(51) Int. Cl. H01L 21/677; G05B 19/418; H01L 21/67

(52) U.S. Cl. CPC H01L 21/67745; G05B 19/41865; H01L 21/67201; H01L 21/67276; H01L 21/67706; H01L 21/67742

(57) ABSTRACT

A wafer processing apparatus may be presented. The apparatus comprising a first loadlock and a second loadlock, at least one extra chambers for preprocessing or postprocessing the wafers, at least one reaction chambers configured to process the wafers, a first wafer handling chamber comprising a first robot, the first robot configured to move wafers between the first and second loadlocks and the extra chambers, a second wafer handling chamber comprising a second robot, the second robot configured to move wafers between the reaction chambers and a pass-through chamber, a pass-through chamber configured to stack wafers from both the first wafer handling chamber and the second wafer handling chamber; and a scheduling unit configured to schedule movements of the plurality of wafers by the first robot and the second robot.

### CROSS-REFERENCE TO RELATED APPLICATION(S)

This Application claims the benefit of U.S. Provisional Application 63/410,687 filed on Sep. 28, 2022, the entire contents of which are incorporated herein by reference.

### FIELD OF INVENTION

The present disclosure relates to an apparatus and a method for processing wafers, particularly to an apparatus and a method that allows for more efficient wafer movement scheduling among the chambers.

### BACKGROUND OF THE DISCLOSURE

Regarding wafers in a wafer processing apparatus, it may be essential to insert wafers into a reaction chamber precisely at the right time. Also, it may be critical for wafers to be ejected from the reaction chamber immediately after their processing is completed.

Therefore, the timing of insertion and ejection of wafers to and from EPI chambers in a wafer processing apparatus may be a critical matter for the quality of the wafers after processing.

Moreover, any kind of bottleneck effect at the chambers would result in low productivity. Therefore, an apparatus and a method to facilitate the movement of wafers among the chambers may be needed.

And process time for EPI product is long, so effective transfer method is required.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a wafer processing apparatus, comprising a first loadlock and a second loadlock, the first and second loadlocks being configured to stack a plurality of wafers and the wafers can be inserted into the first and second loadlocks and the wafers can be removed from the first and second loadlocks; at least one extra chambers for preprocessing or postprocessing the wafers; at least one reaction chambers configured to process the wafers; a pass-through chamber configured to stack wafers received from a first robot and a second robot; a first wafer handling chamber comprising a first robot, the first robot configured to move wafers between the first and second loadlocks, the extra chambers and a pass-through chamber; a second wafer handling chamber comprising a second robot, the second robot configured to move wafers between the reaction chambers and the pass-through chamber; and a scheduling unit configured to schedule movements of the plurality of wafers by the first robot and the second robot.

In at least one aspect, the scheduling unit is configured to schedule the movements of the plurality of wafers by the first robot and the second robot independently and asynchronously of each other.

In at least one aspect, the scheduling unit comprises a processor, a memory and an IO interface, wherein the memory comprises waiting queues.

In at least one aspect, the pass-through chamber further comprises at least one upper chambers and at least one lower chambers for stacking wafers.

In at least one aspect, the upper chambers are configured to receive wafers from the extra chambers and to send the wafers to the reaction chambers, and the lower chambers are configured to receive wafers from the reaction chambers and to send the wafers to the first or second loadlocks.

In accordance with another embodiment, a method of scheduling wafer movements in a scheduling unit of a wafer processing apparatus comprising: preparing a wafer movement time data based on a calculated operation time, wherein wafer movement time data is the time takes for a wafer to move among the chambers and loadlocks; saving the computer wafer movement time data into a waiting queue in a memory of the scheduling unit, wherein the waiting queue stores a second wafer movement time data; determining whether the saved wafer movement time data and the second wafer movement time data in the waiting queue have any time overlaps; updating, if overlap exists, the saved wafer movement time data according to a current time stamp and repeat determining until there is no overlaps; executing, if overlap does not exist, the wafer movement time data saved in the waiting queue; computing the difference between the prepared time data and the actual time taken and reflecting the difference time in the queue's remaining wafer movement time data; and deleting movement time data from the waiting queue.

In at least one aspect, the computing is: computing the difference between the prepared time data and the average time of actually taken time and reflecting the difference time in the queue's remaining wafer movement time data.

In at least one aspect, the method further comprising before executing: determining whether a chamber to be used for wafer movement is currently in use; setting the start time of prechamber process if the chamber to be used is not currently in use; and executing a prechamber process.

In accordance with another embodiment, a non-transitory, computer-readable and tangible medium having stored thereon a set of instructions that are executable by a processor of a computer system to carry out the methods described above.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overall system layout in accordance with an embodiment of the present disclosure.

FIG. 2 illustrates a diagram of scheduling unit in accordance with an embodiment of the present disclosure.

FIG. 3 illustrates a flowchart diagram of a wafer scheduling method in accordance with an embodiment of the present disclosure.

FIG. 4 also illustrates a flowchart diagram of a prechamber processing method in accordance with an embodiment of the present disclosure.

FIG. 5 illustrates an abstract wafer movement example among the chambers and robots in accordance with an embodiment of the present disclosure.

FIG. 6 illustrates an example of updating the wafer movement time data in accordance with an embodiment of the present disclosure.

FIG. 7 illustrates an example of when a time data in the waiting queue is executed (wafer is moving), the difference between the time data and the time actually taken is computed and reflected in the other wafer movement time data for correction.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

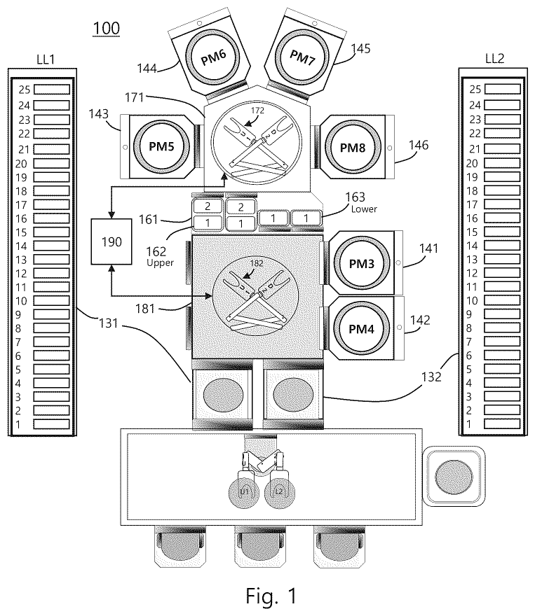

In FIG. 1, a wafer processing apparatus is shown.

A first wafer handling chamber 181 may comprise a first robot 182. The first robot 182 may move wafers among a plurality of loadlocks 131, 132, a plurality of extra chambers 141, 142, and a pass-through chamber 161.

The first loadlock 131 and second the loadlock 132 may be placed beside of the first wafer handling chamber 181. The first/second loadlocks 131, 132 can hold wafers in stacks, which means that the wafers stacked in the first/second loadlocks 131, 132 may not contact with each other.

The extra chambers 141, 142 may be located connected to the first wafer handling chamber 181. The extra chambers 141, 142 may be used to hold and preprocess the wafers before they go into the reaction chambers 143, 144, 145, 146. The extra chambers may be also used for holding the wafers after processing in the reaction chambers (for postprocessing purpose).

The preprocess and postprocess may include cleaning and/or cooling down the wafers.

The number of extra chambers 141, 142 can be 1-8 and only 2 extra chambers are shown in FIG. 1. A pass-through chamber (PTC) 161 may be connected to the first wafer handling chamber 181.

The PTC 161 may comprise Upper chambers 162 and lower chamber 163. The is at least one upper chamber 162 and at least one lower chamber 163. For ease of explanation, 4 upper chambers and 2 lower chambers are depicted in FIG. 1.

The upper chambers 162 may hold wafers from the first/second loadlocks 131, 132. Also, wafers from the upper chambers 162 may go into the reaction chambers 143, 144, 145, 146. The lower chambers 163 may hold wafers from the reaction chambers 143, 144, 145, 146 after wafer processes and wafers from the lower chambers 163 may go into the first or second loadlocks 131, 132.

The wafers may wait at the upper chamber 162 until they are inserted in the reaction chambers 143, 144, 145, 146. After processing, the wafers may be ejected from the reaction chambers 143, 144, 145, 146 and stay at the lower chamber 163 to cool down the heat from the reactions in the reaction chambers 143, 144, 145, 146.

A second wafer handling chamber 171 comprises a second robot 172. The second robot 172 can move wafers between reaction chambers 143, 144, 145, 146 and pass-through chambers 161.

Wafer may be processed in the reaction chambers 143, 144, 145, 146. Due to the reactions take place in the processes, the wafers can be hot when ejected from the reaction chambers 143, 144, 145, 146 and the hot wafers may be cooled down in lower chambers 163.

A scheduling unit 190 may be connected to the first wafer handling chamber 181, first robot 182, second wafer handling chamber 171 and second robot 172. The scheduling unit 190 schedules the movements of wafers.

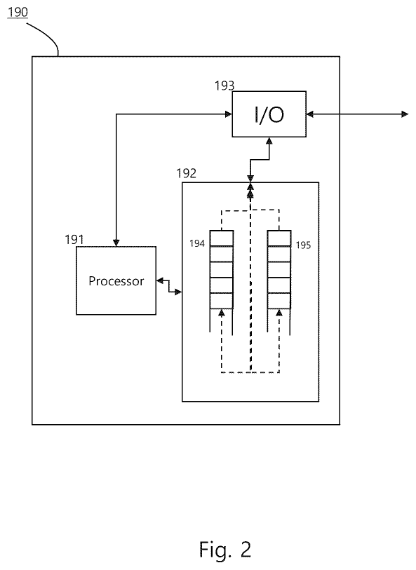

FIG. 2 illustrates the scheduling unit 190. The scheduling unit 190 may comprise: a processor 191 configured to compute the movement times of the wafers; a memory 192 comprising two waiting queues 194 and 195 that are configured to store the movement times of wafers among the loadlocks and chambers by the first robot 182 and second robot 172; and an TO interface configured to receive and send signals.

The present disclosure's apparatus has 2 wafer handling chambers (WHC), i.e., 2 robots (first 182 and second 172). The movement of the first and second robot are independently scheduled in the present disclosure.

When the wafers are in first or second loadlock 131, 132, this is a start time of first robot scheduling. An actual operating time (processing time and moving time) of each module (loadlock, chamber, robot, etc.) may be used for the scheduling.

Every module's operating time may be signaled and recorded and they may be used to calculate an average operating time for each module's wafer movement.

First robot 182, i.e., first WHC 181 and second robot 172, i.e., second WHC 171 has independent scheduling and each scheduling scheme can be inserted into first waiting queue 194 and second waiting queue 195 respectively. However, first WHC 181's and second WHC 171's scheduling time data may be stored in one common waiting queue.

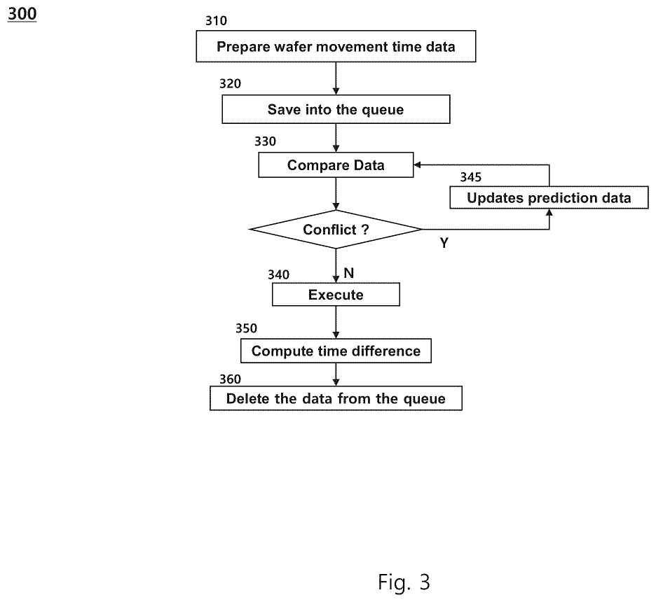

The present disclosure's scheduling method is illustrated in FIG. 3.

Based on the previously recorded operation time, the scheduling unit 190 may calculate the period of time wafers are transported by the first robot (among extra chambers, loadlocks and PTC), and may prepare the wafer transport time period as wafer movement time data (310). The first WHC 181 i.e., first robot 182's scheduling starts when wafers are in first/second loadlock. And the prepared wafer movement time data may be entered into a first waiting queue 194 (320).

For second WHC 171, i.e., second robot 172's scheduling may start when wafers are present in the PTC 161 and the scheduling unit 190 may calculate the period of time wafers are transported by the second robot (among reaction chambers and PTC) and prepares this as wafer movement time data (310). And these prepared wafer movement time data may be saved into a second waiting queue 195 (320).

In the waiting queue (first 194 or second 195), there may exist another time data that were saved earlier. The newly saved time data is compared with the existing time data (330) and checking whether there exist any time conflicts (time overlap).

If there is no conflict (no time overlap), the newly saved time data may remain in the queue unchanged and will be used for wafer processing (340).

If there is conflict (time overlap), then the newly saved wafer movement time data is updated based on the current time (possibly the local time of the place) and the comparison restarts again (345).

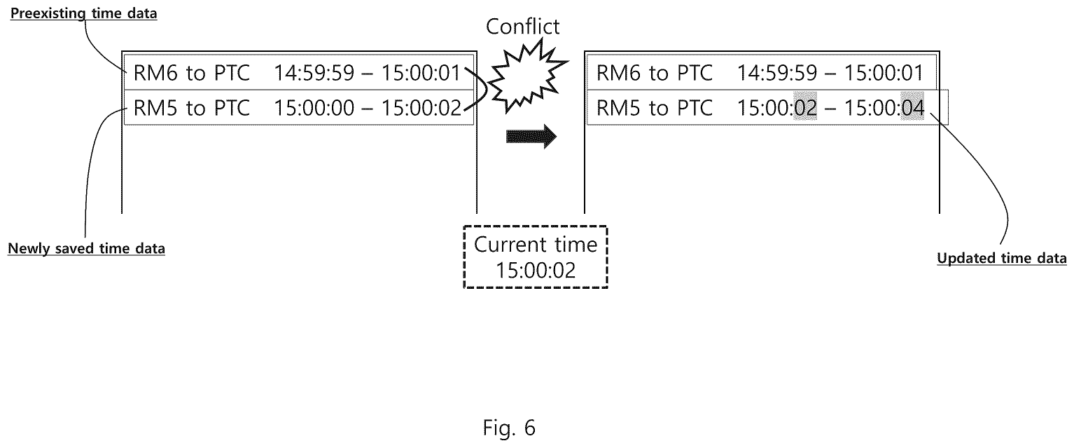

How the wafer movement time data is updated is illustrated as an example in FIG. 6.

If the newly prepared time data is “RM5 [symbol] PTC∥15:00:00 [symbol] 15:00:02” (which means that a wafer is to be transported from reaction chamber 5 to PTC by second robot, i.e., second WHC starting at 15:00:00 and ending at 15:00:02), the transport of the wafer takes a duration of 2 seconds. However, a preexisting time data is “RM6 [symbol] PTC∥14:59:59 [symbol] 15:00:01” (again which means a wafer is to be transported from reaction chamber 6 to PTC by second robot, i.e., second WHC starting at 14:59:59 and ending at 15:00:01).

In this case, the transport should be executed by the second robot so timing for RM5 and RM6 is in conflict. With this conflict, the newly prepared and saved time data is updated with the current time stamp used as a starting time. That means “RM5 [symbol] PTC∥15:00:00 [symbol] 15:00:02” is updated as “RM5 [symbol] PTC∥15:00:02 [symbol] 15:00:04” (Suppose the current time is 15:00:02).

The updating is repeated until there is no conflict (345).

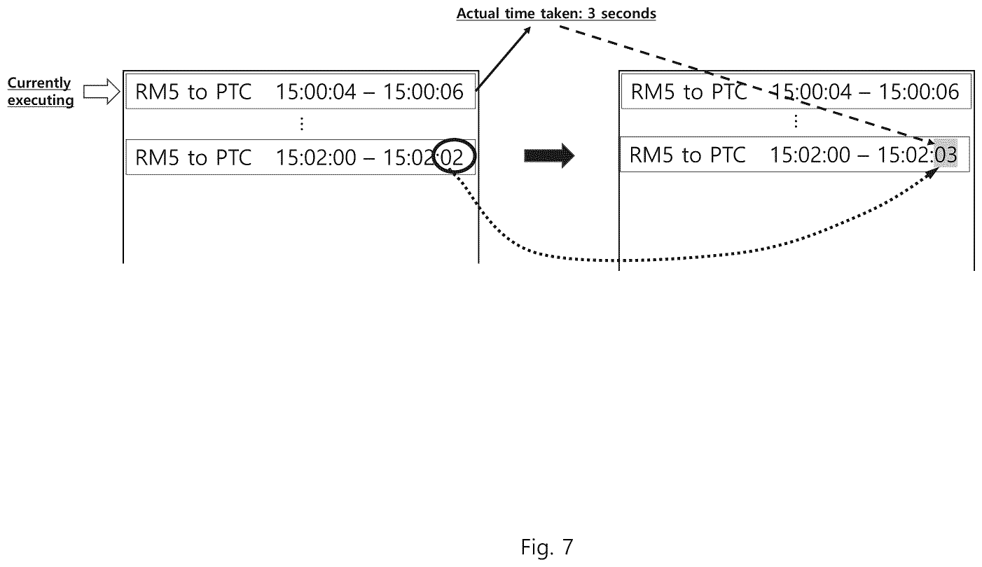

When a time data in the waiting queue is executed (wafer is moving), the difference between the time data and the time actually taken is computed and reflected in the other wafer movement time data for correction (350). FIG. 7 illustrates an example of this situation.

Fig. RM5 to PTC time data is 2 seconds starting at 15:00:04 and 15:02:00. However, actual time taken at 15:00:04 is 3 seconds, not 2 seconds. Therefore, this actual time difference is computed and reflected on the remaining queue's movement time data.

Another way of data reflection can be possible. For example, the average of actual times taken can be used. The accumulated data can be used to derive average time and this can be used to update the remaining queue's movement time data for that module. If this is used, the change of data in FIG. 7 could be some different value other than 3 seconds.

Finally, when wafer is processed, the time data stored on the waiting queue is deleted (360).

Since the present disclosure's scheduling method uses information of staying time and moving (transfer) time between chambers and updating of the transfer schedule by reflecting previous time taken, it would be regarded a predictive scheduling method.

When a wafer processing apparatus starts to process wafers, the quality of the first processed wafers may not be that good compared to that of the latter processed wafers since the reaction chambers of the apparatus is not completely prepared at first.

Therefore, a “prechamber process” which prepares the state of the chamber before inserting actual wafers into the chamber is needed.

In this “prechamber process”, susceptors and gate valves may be operated in the same way as they would have for the ordinary processing of wafer transport to the chamber without wafer in the chamber. However, robot operation (wafer movement) is not associated with the prechamber process.

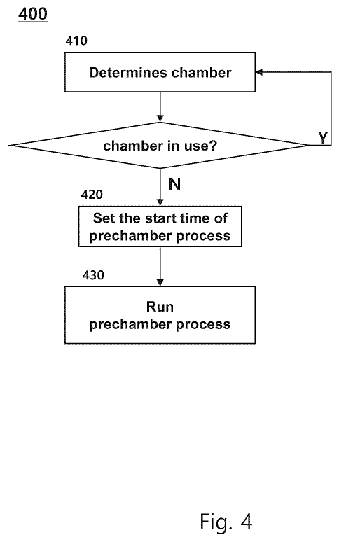

FIG. 4 illustrates the flowchart of prechamber process.

First, a chamber to be processed may be determined whether it is currently in use (410). When the chamber is not in use, the start time of prechamber process is set (420).

After, prechamber process may run multiple times until preparation for the insertion of the actual wafers is completed (430).

For one chamber, one or two times of running the prechamber process before wafer insertion is preferred. This prechamber process may run before the preparing wafer movement time data (310).

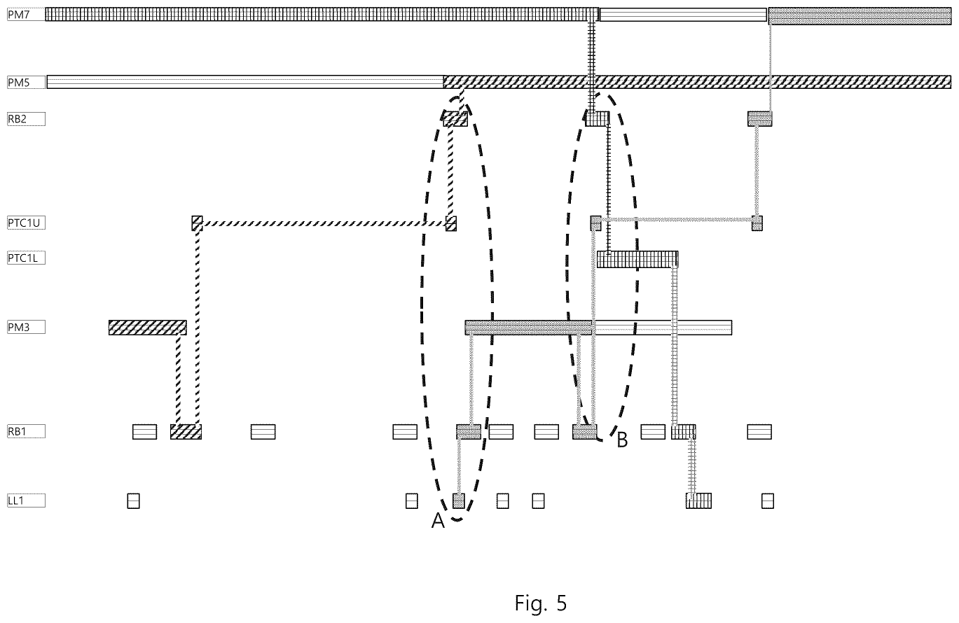

FIG. 5 illustrates the wafer movement according to the present disclosure.

In Area A, a wafer in first loadlock moves to PM 3 (by first robot) while another wafer in the PTC moves to PM 5 (by second robot). And in Area B, a wafer is unloaded from PM 7 to PTC (by second robot) while another wafer in PM 3 moves to PTV (by first robot).

FIG. 5 shows that the present disclosure's apparatus and scheduling method can move wafers by first robot and second robot and the movements are independent an asynchronous of each other.

The above-described arrangements of apparatus and method are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents

1. A wafer processing apparatus, comprising:
a first loadlock and a second loadlock, the first and second loadlocks being configured to stack a plurality of wafers and the wafers can be inserted into the first and second loadlocks and the wafers can be removed from the first and second loadlocks;
at least one extra chambers for preprocessing or postprocessing the wafers;
at least one reaction chambers configured to process the wafers;
a pass-through chamber configured to stack wafers received from a first robot and a second robot;
a first wafer handling chamber comprising a first robot, the first robot configured to move wafers between the first and second loadlocks, the extra chambers and a pass-through chamber;
a second wafer handling chamber comprising a second robot, the second robot configured to move wafers between the reaction chambers and the pass-through chamber; and
a scheduling unit configured to schedule movements of the plurality of wafers by the first robot and the second robot.

2. The wafer processing apparatus according to claim 1, wherein
the scheduling unit comprises a processor, a memory and an IO interface, wherein
the memory comprises waiting queues.

3. The wafer processing apparatus according to claim 1, wherein
the scheduling unit is configured to schedule the movements of the plurality of wafers by the first robot and the second robot independently and asynchronously of each other.

4. The wafer processing apparatus according to claim 1, wherein
the pass-through chamber further comprises at least one upper chambers and at least one lower chambers for stacking wafers.

5. The wafer processing apparatus according to claim 4, wherein
the upper chambers are configured to receive wafers from the extra chambers and to send the wafers to the reaction chambers, and
the lower chambers are configured to receive wafers from the reaction chambers and to send the wafers to the first or second loadlocks.

6. A method of scheduling wafer movements in a scheduling unit of a wafer processing apparatus, the method comprising:
preparing wafer movement time data based on a calculated operation time, wherein wafer movement time data is the time it takes for a wafer to move among chambers and loadlocks;
saving the wafer movement time data into a waiting queue in a memory of the scheduling unit, wherein the waiting queue stores a second wafer movement time data;
determining whether the saved wafer movement time data and the second wafer movement time data in the waiting queue have any time overlaps;
updating, if overlap exists, the saved wafer movement time data according to a current time stamp and repeat determining until there is no overlaps;
executing, if overlap does not exist, the wafer movement time data saved in the waiting queue;
computing a difference between the prepared time data and the actually taken time and reflecting the difference in the queue's remaining wafer movement time data; and
deleting movement time data from the waiting queue.

7. The method according to claim 6, wherein the computing is:
computing a difference between the prepared time data and an average time of actually taken time and reflecting the difference in the queue's remaining wafer movement time data.

8. The method according to claim 6, further comprising before preparing:
determining whether a chamber to be used for wafer movement is currently in use;
setting a start time of prechamber process if the chamber to be used is not currently in use; and
executing a prechamber process.

9. A non-transitory, computer-readable and tangible medium having stored thereon a set of instructions that are executable by a processor of a computer system to carry out a method of scheduling wafer movements in a scheduling unit of a wafer processing apparatus, the instructions, when executed perform the method comprising:
preparing a wafer movement time data based on a calculated operation time, wherein wafer movement time data is the time it takes for a wafer to move among chambers and loadlocks;
saving the wafer movement time data into a waiting queue in a memory of the scheduling unit, wherein the waiting queue stores a second wafer movement time data;
determining whether the saved wafer movement time data and the second wafer movement time data in the waiting queue have any time overlaps;
updating, if overlap exists, the saved wafer movement time data according to a current time stamp and repeat determining until there is no overlaps;
executing, if overlap does not exist, the wafer movement time data saved in the waiting queue;
computing a difference between the prepared time data and the actually taken time and reflecting the difference in the queue's remaining wafer movement time data; and
deleting movement time data from the waiting queue.
